(19) United States
(12) Patent Application Publication
(10) Pub. No.: US 2003/0131180 A1
(43) Pub. Date: Jul. 10, 2003

(54) Device for use in a network environment

(76) Inventors: Chi-Fan Ho, Tamsuei (TW); Tsung-Hao Chen, Taipei (TW)

Correspondence Address: PHILIPS ELECTRONICS NORTH AMERICAN CORP, 580 WHITE PLAINS RD, TARRYTOWN, NY, 10591, US

(21) Appl. No.: 10/233,452

(22) Filed: Sep. 3, 2002

(30) Foreign Application Priority Data
Sep. 3, 2001 (EP) 01203293.4

(51) Int. Cl. G11C 5/00; G06F 12/00

(52) U.S. Cl. 711/1

(57) ABSTRACT

The present invention comprises a device for use in a network environment equipped for upgrading system files, such as OS kernel, device drivers, network stacks and/or remote upgrade/install application, comprising a non volatile memory (15, 66), including:

a first non volatile memory area (11) for storing a copy of the system files;

a second non volatile memory area (12) for storing another copy of the system files;

a third non volatile memory area (13) for storing one or more boot files for booting the device using the system files that are stored in either the first memory (11) or the second memory (12).

Over recent years the use of computing devices which are connected to a network, either a wired network or a wireless network, is becoming more and more within reach of every day use either in private or business environments. After devices are produced, further development in software that can be used in these devices is achieved. It is therefore preferable that users can upgrade their software. In case of applications software, users can upgrade them using the network they are connected to. This can be done safely wherever they are. Whenever anything goes wrong during such an upgrade procedure corrupted files that are a result of such a wrongful procedure can be deleted and the procedure can be repeated.

More or less the same applies for upgrading system files that the computing device is for booting or rebooting itself. However, upgrading such files is more risky than upgrading application files. If anything goes wrong during updating, the system files a network device will not be able to reboot due to corrupted system files. Such a device will thereafter be useless unless relatively very costly repairs are being made if such repairs are achievable at all.

In order to overcome such disadvantages the present invention provides a device for use in a network environment equipped for upgrading system files, such as OS kernel, device drivers, network stacks and/or remote upgrade/install application, comprising a non volatile memory, including:

a first non volatile memory area for storing a copy of the system files;

a second non volatile memory area for storing another copy of the system files;

a third non volatile memory area for storing one or more boot files for booting the device using the system files that are stored in either the first memory or the second memory.

As such a device according to the invention comprises two redundant non volatile memory areas containing the system files necessary for rebooting the device, a new device can always reboot whenever an upgrade has gone wrong. In such an event if one copy of the system files are corrupted the other set of system files can be used. An event in which a software upgrade fails can be that the network device looses it's power supply during the upgrade phase which is not unlikely to happen using battery powered devices such as PDA's or mobile phones or using electricity grid powered devices without an uninterrupted power supply (UPS).

A preferred embodiment according to the invention provides a computing device comprising a personal computer. Other embodiments may comprise set top boxes, mobile phones, personal digital systems or handheld computers. All of these devices are used in environments wherein software upgrades after production may increase usability or comfort of use.

Furthermore, it is preferred that the device comprises at least a fourth memory area for storing application files. Such a fourth memory area could be another non volatile memory area which contains application programmes. Furthermore, such a device can be equipped with any kind of data storage device, such as hard drives, flash memories, etc.

A further preferred embodiment of the device uses a network for transporting data for upgrading the system software. This embodiment has the great advantage that for upgrading system software, it is not required that the user fiscally connects a data carrier containing upgrades to the device. It is even achievable that the supplier of the device, either being the manufacturer or some service provider, upgrades the system software without the user even notices this being done. This is called a transparent update. It is also possible that the user wants to update the software and initiates an update himself.

In another embodiment of the invention the third non volatile memory area comprises software for determining a memory corruption status (SRS) for indicating whether the first and/or second memory is either corrupt or in good working order. In this embodiment it is preferred that the system rescue status comprises values, such as “first and second memory area in good working order” (“all safe”), “first non volatile memory area in good working order” (“first safe”) and/or “second non volatile memory area in good working order” (“second safe”).

Furthermore, it is preferred that these variables comprise Boolean values for “all safe”, “first safe”, and/or “second safe”. Using such Boolean values enables the method that is described hereafter to decide which memory area to use during to boot up of the computing device.

A preferred embodiment of the invention provides a method for booting the device, comprising steps for:

checking whether the Boolean value for “all safe” is “yes”;

booting from the first or the second non volatile memory area when “all safe” is determined to be “yes”.

If both the memory areas containing the system files are not corrupted the Boolean value for each variable “all safe” will be “yes”. This has the advantage the boot up sequence of the device knows that both areas are safe to use for booting the device.

A further embodiment of the method according to the invention comprises steps for:

checking whether the Boolean value for “first safe” is “yes”;

copying the content of the first non volatile memory area into the second non volatile memory area when “first safe” is determined to be “yes”;

setting the Boolean for “all safe” and “second safe” to be “yes”;

booting from the first or the second non volatile memory area.

Furthermore, an embodiment of the method according the invention comprises the steps of:

checking whether the Boolean value for “second safe” is “yes”;

copying the content of the second non volatile memory area into the first non volatile memory area when “second safe” is determined to be “yes”;

setting the Boolean for “all safe” and “second safe” to be “yes”;

booting from the first or the second non volatile memory area.

These two embodiments have the advantage that during boot up of the device it is recognized that either one of the memory areas is corrupted, e.g. by a power loss during upgrading of the system files. It is very advantageous that the corrupted memory area will be restored using the second identical contents of the not corrupted remaining memory area containing the system files. Using this method such a device will not render useless whenever an upgrade of the system files fails.

A further embodiment of the invention provides a method for upgrading the system files of a device, comprising steps of:

connecting to an upgrade server containing at least an upgrade of the system files;

downloading the upgrade of the system files,

setting the value of the “first safe” and “all safe” Boolean variables to “no”;

storing the upgrade of the system files in the first memory;

setting the value of the “first safe” boolean variable to “yes”.

Furthermore, it is preferred that this embodiment comprises steps for setting the Boolean variable of the second memory to “no”.

Advantages of these embodiments are that by setting the Boolean values of “first safe” and “all safe” to “no”, it will be apparent for the boot sequence that the system files in this memory area are corrupt if the upgrade of these system files fails. By setting the Boolean variable of the second memory to “no” after the value of the “first safe” Boolean variable is set to “yes” the device will boot using the upgraded system files of the first memory area as the second memory area is indicated to be corrupted.

In order for the second memory area to be “bootable” a further embodiment comprises steps for:

storing the upgrade of the system files in the second memory;

setting the value of the “second safe” Boolean variable to “yes”;

setting the Boolean variable for “all safe” to “yes”.

An advantage of this procedure is that whenever during the method for upgrading the system files the method fails, e.g. because of a power interruption, the device will be able to boot using the memory area that is not indicated to be corrupted.

Further advantages, features and details of the present invention will be elucidated in the light of the following description of a preferred embodiment thereof with reference to the annexed drawings, in which:

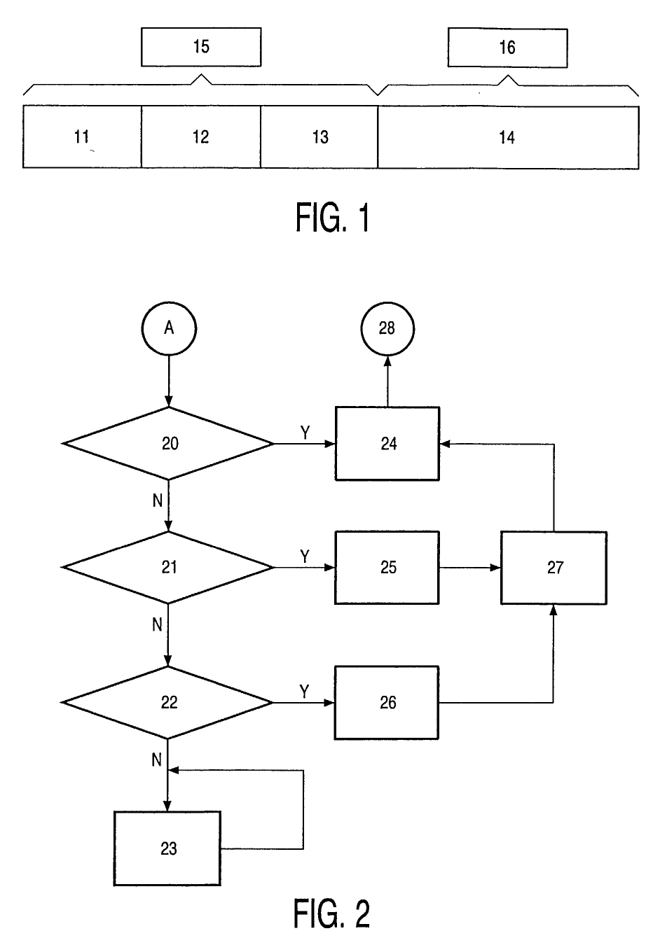

FIG. 1 is a diagram of an embodiment according to the present invention;

FIG. 2 is a flow diagram of an embodiment according to the present invention;

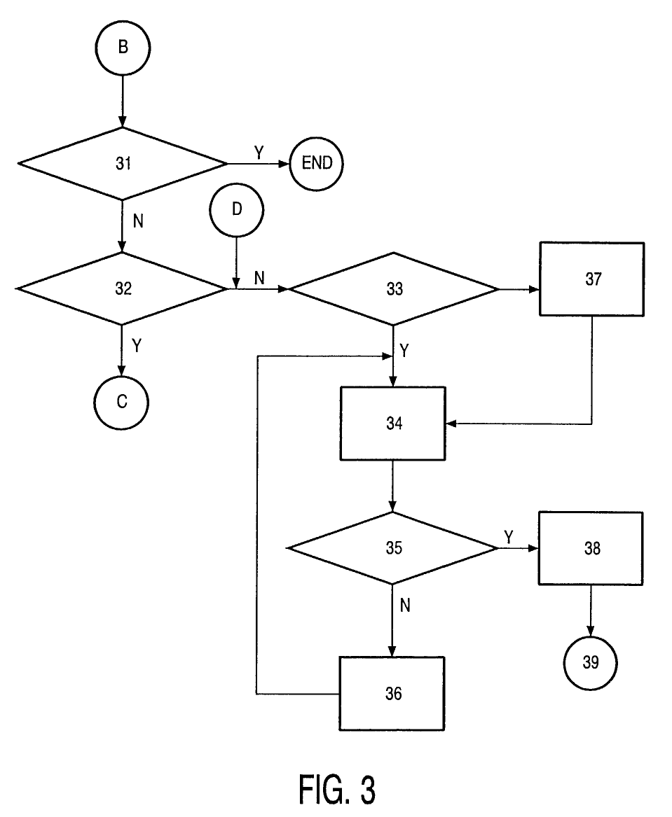

FIG. 3 is a flow diagram of another embodiment according to the present invention;

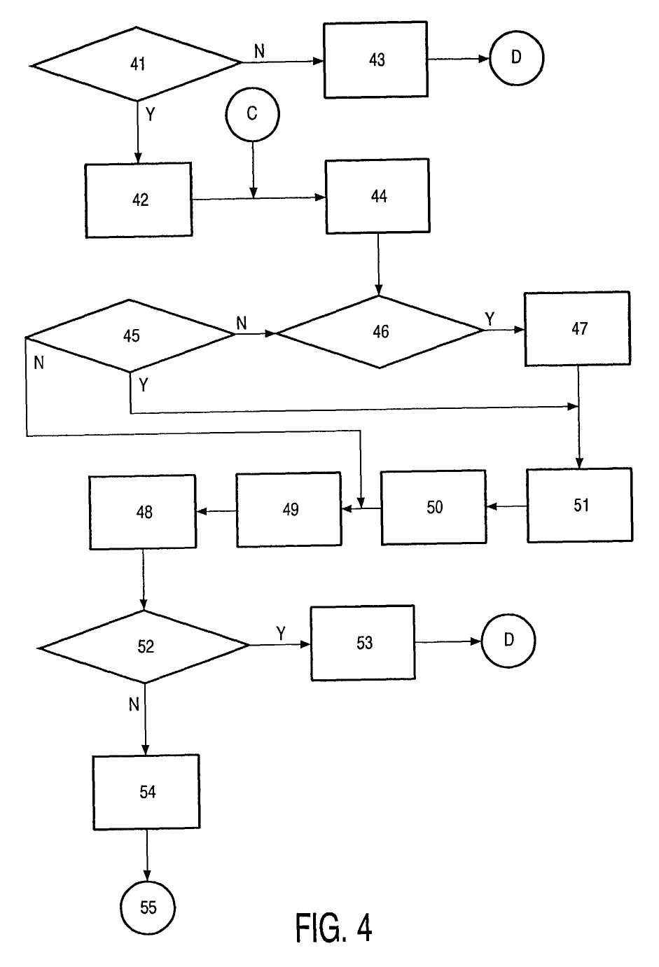

FIG. 4 is a flow diagram of another embodiment according to the present invention; and

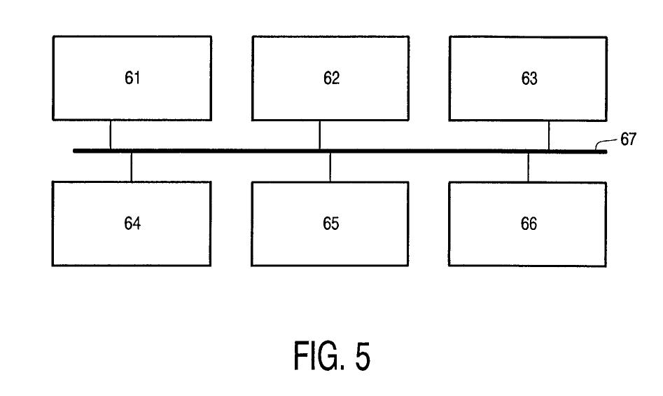

FIG. 5 is a diagram of a preferred embodiment according to the present invention.

An embodiment of the present invention (FIG. 1) provides a non-volatile or flash memory storage system comprising a hidden memory area 11, 12, 13 and a file system area 14. In the file system memory area application programmes that can be used in the network device are stored. The hidden area is divided in three distinct memory areas. The first thereof is the boot rescue area in which data are stored for determining the validity of the other two memory areas. The second memory area of the hidden area is the first core image area 12. In this first core image area operating system files are stored that are needed for booting the network device. These files include “OS kernel” (which is the fundamental part of an Operating System closest to the hardware and may activate the hardware directly or interface to another software layer that drives the hardware), “Device Drivers”, “Network Stacks”, “Remote Upgrade/Install Application” files. In the second core image area 13 a copy of these files is stored. Redundantly storing copies of files in this manner has certain advantages. If during an up-date of these files of the network device over the network connection errors occur and therefore the files become corrupted, the system will be capable of booting from the copy of the core image area that is not corrupted.

In FIG. 2, a method for booting the network device using the boot rescuer area and the first and second core image area is depicted. The method starts in “A” by turning on the network device. In 20 it is checked whether a variable “system rescue status” (SRS) has the value “all safe”. If the variable SRS has the value “all safe”, this means that both the first core image area and the second core image area are not corrupted or in good working order. In this case the device is booted from the first core image area in 24 after which this method ends.

When in 20 it is asserted that the SRS has the value “all safe”, it is determined whether the value of SRS is “first safe” in 21. When this is the case, the files in the first core image area of the hidden area as described in the above are not corrupted or in good working order. As the variable SRS has the value “all safe” in this case the files in the second core image area are thus corrupted or not in good working order. Hereafter, in 25, the files from the first core image area are copied into the second core image area thereby restoring the files in the second core image area. Thereafter the SRS is set to “all safe” in 27. Thereafter, the network device is booted from the first core image area and the method ends in 28.

When in 21 it is asserted that the SRS has the value “first safe” in 22 it is determined whether the value of SRS is “second safe” is determined. When the variable SRS is “second safe”, in 26 the files of the second core image area are copied into the first core image area in a similar way as described in step 25. Hereafter in 27 the value of the variable SRS is set to “all safe”. Finally, the network device is booted from the first core image area in 24 whereafter the method ends in 28.

When it is asserted that the variable SRS has the value “second safe” in 22, this means that no core image area exists with non-corrupted files. Therefore, the network device will be unable to boot and in 23 a repair message is displayed in a display of the network device.

Another embodiment according to the invention is depicted in FIG. 3. This method pertains to upgrading of application files by the network device. After starting in B the method determines a value of the variable “application upgrade status” (AUS) in 31. When the value of AUS is “all installed” in 31 the method ends. When the value of AUS is not determined to be “all installed” in 31, it is determined in 32 whether the value of AUS is “core image upgrade start in 32. When the answer to the question of 32 is yes, the method continues in C, which is further referred to in relation to FIG. 4. When the value of AUS is not determined to be “core image upgrade starts” in 33 it is determined whether the value of AUS is an “application serial number”. An “application serial number” is an ID number of an application component. The method depicted in this figure uses an application serial number to communicate with an upgrade serve for downloading the application component that is referred to by the application serial number.

Another input to 33 is “D”. The steps leading to D are further described in relation to FIG. 4. When it is determined in 33 that the variable AUS comprises a valid application serial number, the method connects to an upgrade server for downloading and upgrading desired application files according to the application serial number in 34. When in 33 it is determined that AUS does not comprise a valid application serial number, in 37 AUS is set to the value “first application serial number”. This value is a special application serial number to indicate downloading of all application component files. Hereafter, these application component files are downloaded in 34.

After downloading files in 34, in 35 the method checks whether the upgrade is finished in 35. When the answer to this question is yes, AUS is set to “all installed” in 38 after which the method ends in 39. If in 35 it is determined that the upgrade is not yet finished, the AUS is set to the next application serial number in 36 whereafter the method continues and repeats in 34.

In FIG. 4 another embodiment of a method according to the invention is depicted. This embodiment relates to the upgrading of the core image files. In 41 it is determined whether the core image is to be upgraded. When the answer to this question is determined to be no, in 43 the variable AUS is set to “application files upgrade start”. Hereafter, the method continues in D, which refers to the D of FIG. 3 that is an input to 33.

When in 41 it is determined that the core image files are to be upgraded, in 42 the variable AUS is set to “core image upgrade start”. Hereafter, the network device connects to the upgrade server and downloads the core image files to RAM. Another input to 44 is “C” coming from FIG. 3.

After the core image files are downloaded to RAM in 44, in 46 it is determined whether the variable “system rescue status” (SRS) is “all safe”. If SRS is not “all safe” then in 45 it is determined whether the variable SRS is “first safe”. When in 46 it is determined that the variable SRS has the value “all safe”, then in 47 the variable SRS is set to be “first safe”. Hereafter, in 51 the core image files from RAM is copied to the second core image area. This step is also performed when the answer of 45 is yes. Hereafter in 50 the SRS is set to be “second safe”. Hereafter, the core image file from RAM is copied to the first core image area, which step is also performed when the answer to 45 is no.

After copying the core image files from RAM to the first core image area in 49, the SRS is set to “all safe” and the AUS is set to “application files upgrade start” in 48.

Hereafter, in 49, it is determined whether application files are to be upgraded in 52. If the answer to this question of 52 is yes, the variable AUS is set to be “application files upgrade start” in 53 whereafter the method continues in “D”. When the answer to the question of 52 is no, the variable is set to “all installed” in 54, whereafter the method ends in 55.

In FIG. 5 another embodiment according to the invention is depicted. Components 61-66 are parts of a network device using the above methods and memory configuration. A processor 61, random access memory 62, input device 63, display device 64 and data storage device 65 can be found in numerous computing devices according to the state of the art. The flash memory 66 is configured as non-volatile memory areas 11-13 and 14 of FIG. 1. This flash memory is used by the network device according to the above description. The components 61-66 are interconnected by a bus 67.

1. Device for use in a network environment equipped for upgrading system files, such as OS kernel, device drivers, network stacks and/or remote upgrade/install application, comprising a non volatile memory, including:
a first non volatile memory area for storing a copy of the system files;
a second non volatile memory area for storing another copy of the system files;
a third non volatile memory area for storing one or more boot files for booting the device using the system files that are stored in either the first memory or the second memory.

2. Device according to claim 1 further comprising a personal computer.

3. Device according to claim 1 further comprising one or more of the following devices: set top box, mobile phone, personal digital assistant, handheld computer.

4. Device according to one or more of the preceding claims comprising at least a fourth memory area for storing application files.

5. Device according to one or more of the preceding claims in which a network is used for transporting data for upgrading the system software.

6. Device according to one or more of the claims 1-5 in which the third non volatile memory area comprises software for determining a memory corruption status for knowing whether the first and/or second memory is either corrupt or in good working order.

7. Device according to claim 6 in which the system rescue status comprises values such as “first and second memory area in good working order” (“all safe”), “first non volatile memory area in good working order” (“first safe”) and/or “second non volatile memory area in good working order” (“second safe”).

8. Device according to claim in which the system rescue status comprises Boolean values for “all safe”, “first safe”, and/or “second safe”.

9. Method for booting a device for use in a network equipped for upgrading system files, such as OS kernel, device drivers, network stacks and/or remote upgrade/install application comprising a non-volatile memory with a first and second memory area containing identical copies of the system files comprising the steps of:
checking whether the memory area is in good working order;
copying the contents of a memory area that is in good working order to a corrupted memory area, if the other is not in good working order;
booting the device using one of the memory area's.

10. Method for booting a device according to the claims 1-8, comprising steps of:
checking whether the Boolean value for “all safe” is “yes”;
booting from the first or the second non volatile memory area when “all safe” is determined to be “yes”.

11. A method according to claim 9 or 10 for booting the device according to the claims 1-8, further comprising steps of:
checking whether the Boolean value for “first safe” is “yes”;
copying the content of the first non volatile memory area into the second non volatile memory area when “first safe” is determined to be “yes”;
setting the Boolean for “all safe” and “second safe” to be “yes”;
booting from the first or the second non volatile memory area.

12. Method according to claim 9 or 10 for booting a device according to the claims 1-8, further comprising steps of:
checking whether the Boolean value for “second safe” is “yes”;
copying the content of the second non volatile memory area into the first non volatile memory area when “second safe” is determined to be “yes”;
setting the Boolean for “all safe” and “second safe” to be “yes”;
booting from the first or the second non volatile memory area.

13. Method for upgrading the system files of a device according to the claims 1-8 comprising the steps of:
connecting to an upgrade server containing at least an upgrade of the system files;
downloading the upgrade of the system files,
setting the value of the “first safe” and “all safe” Boolean variables to “no”;
storing the upgrade of the system files in the first memory;
setting the value of the “first safe” boolean variable to “yes”.

14. Method according to claim 13 further comprising steps for setting the Boolean variable of the second memory to “no”.

15. Method according to claim 13 or 14, further comprising steps for:
storing the upgrade of the system files in the second memory;
setting the value of the “second safe” Boolean variable to “yes”;
setting the Boolean variable for “all safe” to “yes”.

16. Computer program product arranged for causing a processor to execute the method of claim 9 or 10.

17. Computer program product arranged for causing a processor to execute the method of claim 13.
